(19) United States
(12) Patent Application Publication
(10) Pub. No.: US 2025/0118620 A1
(43) Pub. Date: Apr. 10, 2025

(54) SEMICONDUCTOR PACKAGE

(71) Applicant: SAMSUNG ELECTRONICS CO., LTD., Suwon-si (KR)

(72) Inventors: Young-Deuk Kim, Suwon-si (KR); Heejung Hwang, Suwon-si (KR)

(21) Appl. No.: 18/732,444

(22) Filed: Jun. 3, 2024

(30) Foreign Application Priority Data
Oct. 6, 2023 (KR) 10-2023-0133668

(51) Int. Cl. H01L 23/367; H01L 21/48; H01L 23/00; H01L 23/498; H01L 25/18; H10B 80/00

(52) U.S. Cl. CPC H01L 23/3677; H01L 23/49822; H01L 23/49833; H01L 23/49838; H01L 25/18; H01L 21/4857; H01L 24/16; H01L 24/32; H01L 24/73; H01L 2224/16225; H01L 2224/32225; H01L 2224/73204; H01L 2924/1431; H01L 2924/1436; H01L 2924/1437; H01L 2924/1438; H10B 80/00

(57) ABSTRACT

Disclosed is a semiconductor package including a wiring substrate, an external connection terminal on a bottom surface of the wiring substrate, an interposer substrate on a top surface of the wiring substrate, a first semiconductor chip on the interposer substrate, and a first chip stack on the interposer substrate and horizontally spaced apart from the first semiconductor chip. The wiring substrate includes a core, an upper redistribution layer covering a top surface of the core, and a lower redistribution layer covering a bottom surface of the core. The core includes core through vias vertically penetrating the core, and a first thermal radiation structure below the first chip stack and in the core. The first thermal radiation structure is electrically insulated from the upper and lower redistribution layers. A thermal conductivity of the first thermal radiation structure is greater than that of the core.

### CROSS-REFERENCE TO RELATED APPLICATION

This U.S. nonprovisional application claims priority under 35 U.S.C § 119 to Korean Patent Application No. 10-2023-0133668 filed on Oct. 6, 2023, in the Korean Intellectual Property Office, the disclosure of which is hereby incorporated by reference in its entirety.

### BACKGROUND

With the development of electronic industry, electronic products have increasing demands for high performance, high speed, and compact size. To meet the trend, there has recently been developed a packaging technology in which a plurality of semiconductor chips are mounted in a single package.

Portable devices have been increasingly demanded in recent electronic product markets, and as a result, it has been ceaselessly required for reduction in size and weight of electronic parts mounted on the portable devices. In order to accomplish the reduction in size and weight of the electronic parts, there is need for technology to integrate a number of individual devices into a single package as well as technology to reduce individual sizes of mounting parts.

### SUMMARY

The present disclosure relates to a semiconductor package with improved thermal stability, improved structural stability and a method of fabricating the same, and more particularly, to a stacked semiconductor package in which a plurality of semiconductor chips are stacked on a substrate and a method of fabricating the same.

The object of the present disclosure is not limited to the items mentioned above, and other objects which have not been mentioned above will be clearly understood to those skilled in the art from the following description.

A semiconductor package may include: a wiring substrate; an external connection terminal on a bottom surface of the wiring substrate; an interposer substrate on a top surface of the wiring substrate; a first semiconductor chip on the interposer substrate; and a first chip stack on the interposer substrate and horizontally spaced apart from the first semiconductor chip. The wiring substrate may include: a core section; an upper redistribution layer that covers a top surface of the core section; and a lower redistribution layer that covers a bottom surface of the core section. The core section may include: a plurality of core through vias that vertically penetrate the core section; and a first thermal radiation structure below the first chip stack and in the core section. The first thermal radiation structure may be electrically insulated from the upper and lower redistribution layers. A thermal conductivity of the first thermal radiation structure may be greater than a thermal conductivity of the core section.

A semiconductor package may include: a first redistribution layer; a core section on the first redistribution layer, the core section having a central region and a peripheral region that surrounds the central region; a thermal radiation metal in the core section on the peripheral region; a second redistribution layer on the core section; a first chip stack on the second redistribution layer on the peripheral region, the first chip stack including a plurality of memory chips vertically stacked; and a logic chip on the second redistribution layer on the central region and horizontally spaced apart from the first chip stack. The thermal radiation metal may be spaced apart from top and bottom surfaces of the core section.

A semiconductor package may include: a core section; a thermal radiation structure in the core section; a first redistribution layer and a second redistribution layer respectively on a top surface and a bottom surface of the core section, each of the first and second redistribution layers including a dielectric pattern and wiring pattern in the dielectric pattern; an interposer substrate on the first redistribution layer; a first semiconductor chip on the interposer substrate; and a plurality of chip stacks on the interposer substrate and horizontally spaced apart from the first semiconductor chip, each of the plurality of chip stacks including a plurality of second semiconductor chips that are vertically stacked. The thermal radiation structure may vertically overlap the plurality of chip stacks.

### BRIEF DESCRIPTION OF THE DRAWINGS

FIG. 1 illustrates a cross-sectional view showing an example semiconductor package.

FIG. 2 illustrates an enlarged view of section C depicted in FIG. 1, showing a wiring substrate.

FIGS. 3 to 5 illustrate plan views showing an example semiconductor package.

FIGS. 6 to 8 illustrate cross-sectional views showing an example semiconductor package.

FIG. 9 illustrates a plan view showing an example semiconductor package.

FIGS. 10 to 14 illustrate cross-sectional views showing a method of fabricating an example semiconductor package.

### DETAILED DESCRIPTION

The following will now describe a semiconductor package according to the present disclosure with reference to accompanying drawings.

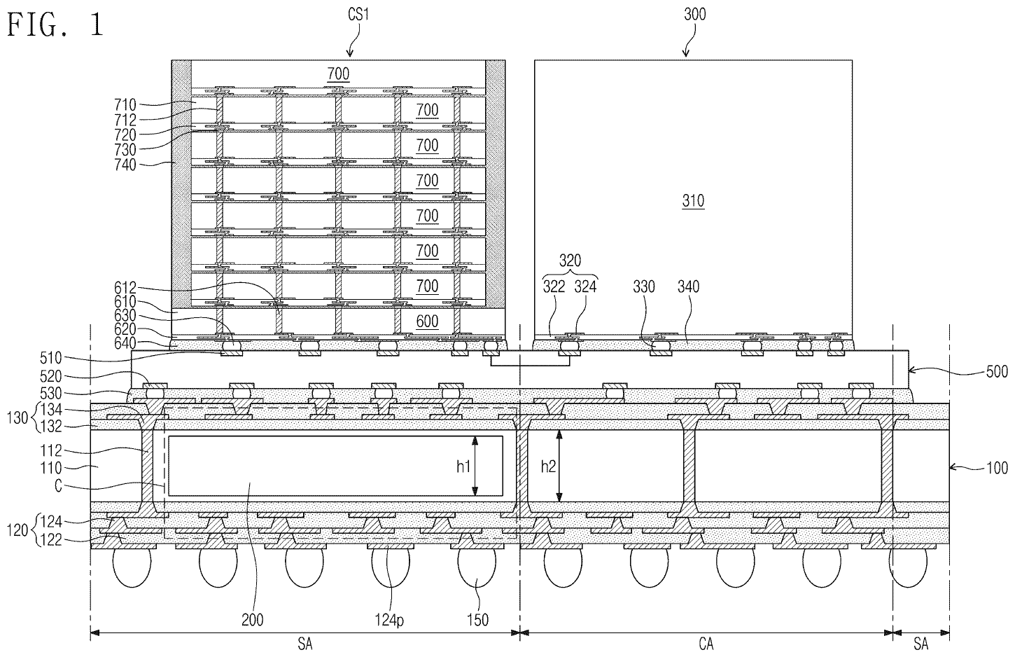

FIG. 1 illustrates a cross-sectional view showing an example semiconductor package.

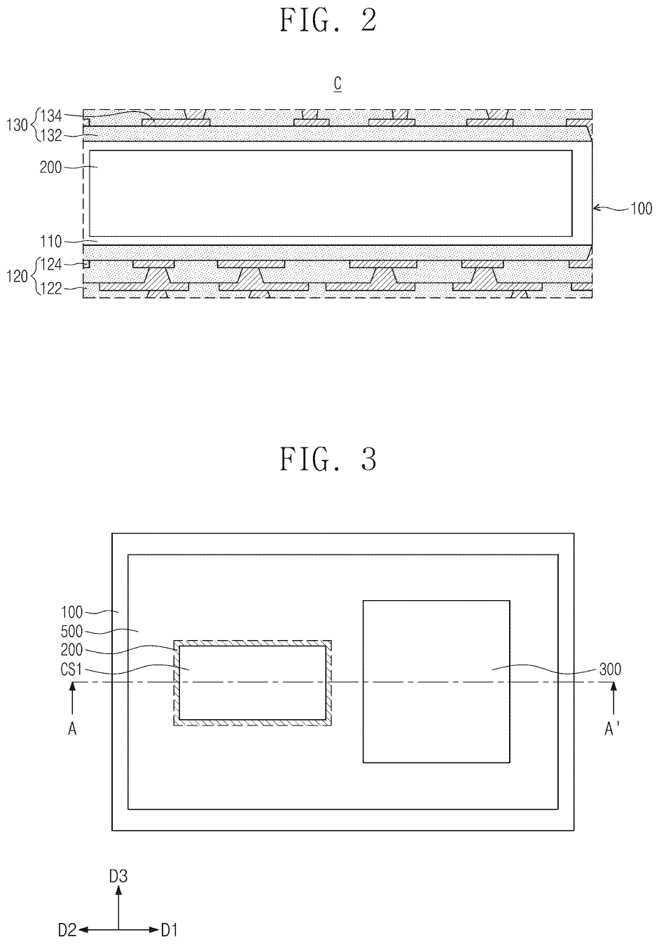

FIG. 2 illustrates an enlarged view of section C depicted in FIG. 1, showing a wiring substrate.

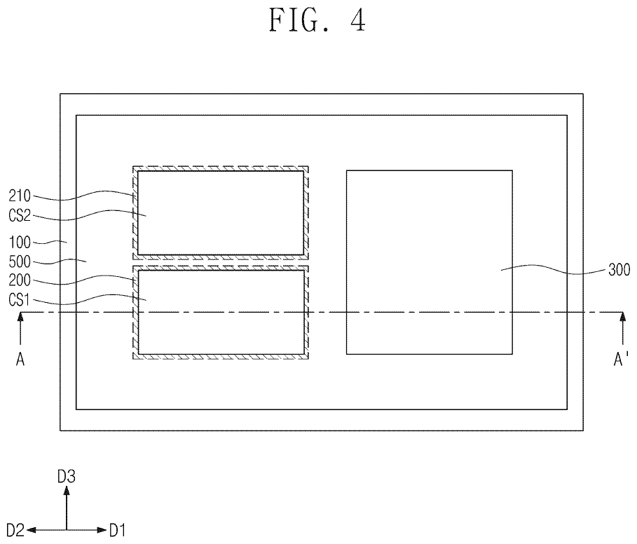

FIGS. 3 to 5 illustrate plan views showing an example semiconductor package. FIG. 1 shows a cross-sectional view taken along line A-A′ of FIGS. 3 to 5.

In this description below, symbol D1 of FIG. 3 may be called a first direction, symbol D2 of FIG. 3 may be called a second direction opposite to the first direction D1, and symbol D3 of FIG. 3 may be called a third direction that intersects the first direction D1 and the second direction D2.

Referring to FIGS. 1 and 2, a wiring substrate 100 may be provided. The first, second, and third directions D1, D2 and D3 may be parallel to a top surface of the wiring substrate 100. The wiring substrate 100 may include a core section 110, a lower redistribution layer 120 provided on a bottom surface of the core section 110, and an upper redistribution layer 130 provided on a top surface of the core section 110.

The core section 110 may have a plate shape. When viewed in plan, the core section 110 may include a single core pattern. Although the core section 110 having a single core pattern is discussed by way of example, the present disclosure is not limited thereto. According to some implementations, the core section 110 may include two or more core patterns. For example, the wiring substrate 100 may include a plurality of core patterns that are spaced apart from each other when viewed in plan. The core section 110 may include a central region CA and a peripheral region SA.

In this description, the central region CA of the core section 110 may be an area on which a first semiconductor chip 300 is provided as will be discussed below and may be positioned below the first semiconductor chip 300. In addition, although it is named as the central region CA, it may not be limited that the central region CA is an area on a center of the core section 110, and the central region CA may be defined to indicate any partial area of the core section 110 below the first semiconductor chip 300.

In this description, the peripheral region SA of the core section 110 may be defined to indicate an area other than the central region CA in the core section 110. In addition, although it is named as the peripheral region SA, it may not be limited that the peripheral region SA is an area on an edged of the core section 110, and the peripheral region SA may be defined to indicate a remaining area other than the central region CA or a partial area of the core section 110 below a first chip stack CS1 which will be discussed below. The core section 110 may include a dielectric material. For example, the core section 110 may include a dielectric polymer or a glass.

On the peripheral region SA, a first thermal radiation structure 200 may be provided in the core section 110. The first thermal radiation structure 200 may be provided as a portion of the core section 110, but in the present implementation, the core section 110 and the first thermal radiation structure 200 will be regarded separate components for convenience of description.

The first thermal radiation structure 200 may include a material to outwardly transfer heat generated from a first chip stack CS1 which will be discussed below. For example, the first thermal radiation structure 200 may include a metallic material, a ceramic material, a carbon material, or a polymeric material having a high thermal conductivity. The first thermal radiation structure 200 may have a thermal conductivity greater than that of the core section 110. In this description, the term “thermal conductivity” may mean the degree to which a substance having a specific shape and size actually transfers heat. The thermal conductivity of each of the first thermal radiation structure 200 and the core section 110 may denote an average of thermal conductivity of materials included in each component.

The first thermal radiation structure 200 may have a first thickness h1. For example, the first thickness h1 may be a distance from a bottom surface to a top surface of the first thermal radiation structure 200. The first thickness h1 of the first thermal radiation structure 200 may be less than a second thickness h2 that is a distance from the bottom surface to the top surface of the core section 110. The first thermal radiation structure 200 may be spaced apart from the top and bottom surfaces of the core section 110. The core section 110 may separate each of the upper and lower redistribution layers 130 and 120 from the first thermal radiation structure 200. For example, the core section 110 may extend between the first thermal radiation structure 200 and the upper redistribution layer 130 and between the first thermal radiation structure 200 and the lower redistribution layer 120.

The first thermal radiation structure 200 may not be electrically connected to any of the upper redistribution layer 130 and the lower redistribution layer 120. For example, the first thermal radiation structure 200 may be spaced apart from the upper redistribution layer 130 and the lower redistribution layer 120 and may be electrically floated in the wiring substrate 100.

FIG. 1 depicts that the first thickness h1 of the first thermal radiation structure 200 is less than the second thickness h2 of the core section 110, but the present disclosure is not limited thereto. According to some implementations, the first thickness h1 of the first thermal radiation structure 200 may be the same as the second thickness h2 of the core section 110. The first thermal radiation structure 200 may vertically penetrate the core section 110 to be exposed on the top and bottom surfaces of the core section 110.

Referring to FIG. 1, the core section 110 may include a core through via 112. The core through via 112 may be horizontally spaced apart from the first thermal radiation structure 200. The core through via 112 may vertically penetrate the core section 110. The core through via 112 may extend from the top surface toward the bottom surface of the core section 110. The core through via 112 may be exposed on the top surface of the core section 110 and on the bottom surface of the core section 110. The core through-via 112 may connect, e.g., electrically connect, the upper redistribution layer 130 to the lower redistribution layer 120. The core through via 112 may be provided in plural, if necessary. The core through via 112 may include a conductive material. For example, the core through via 112 may include a metallic material, such as copper (Cu), aluminum (Al), silver (Ag), tin (Sn), gold (Au), nickel (Ni), lead (Pb), titanium (Ti), or any alloy thereof.

The lower redistribution layer 120 may be provided on the bottom surface of the core section 110. The lower redistribution layer 120 may correspond to a redistribution layer for redistribution of the wiring substrate 100. The lower redistribution layer 120 may cover the bottom surface of the core section 110. The lower redistribution layer 120 may include one or more lower wiring layers that are sequentially stacked on the bottom surface of the core section 110. Each of the lower wiring layers may include a lower dielectric pattern 122 and a lower wiring pattern 124. The lower wiring pattern 124 of one lower wiring layer may be electrically connected to the lower wiring pattern 124 of an adjacent lower wiring layer. The following will describe the lower dielectric pattern 122 and the lower wiring pattern 124 of one lower wiring layer.

The lower dielectric pattern 122 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers.

The lower wiring pattern 124 may be provided on the lower dielectric pattern 122. The lower wiring pattern 124 may be provided on a bottom surface of the lower dielectric pattern 122. The lower wiring pattern 124 may protrude onto the bottom surface of the lower dielectric pattern 122. The lower wiring pattern 124 may horizontally extend on the bottom surface of the lower dielectric pattern 122. On the bottom surface of the lower dielectric pattern 122, the lower wiring pattern 124 may be covered with the lower dielectric pattern 122 of an underlying lower wiring layer. As discussed above, the lower wiring pattern 124 may be a pad or wiring part of the lower wiring layer. For example, the lower wiring pattern 124 may be a component of horizontal redistribution in the lower redistribution layer 120.

The lower wiring pattern 124 may not be electrically connected to the first thermal radiation structure 200. For example, the lower wiring pattern 124 may be spaced apart from the first thermal radiation structure 200 across the lower dielectric pattern 122 or the core section 110. In another example, when the first thermal radiation structure 200 is exposed on the bottom surface of the core section 110, the lower dielectric pattern 122 may separate the lower wiring pattern 124 from the first thermal radiation structure 200. The lower wiring pattern 124 may include a conductive material. For example, the lower wiring pattern 124 may include copper (Cu).

The lower wiring pattern 124 may have a damascene structure. For example, the lower wiring pattern 124 may have a via that protrudes onto a top surface thereof. The via may be a component for a vertical connection between the lower wiring patterns 124 of neighboring lower wiring layers. For example, the via may extend from the top surface of the lower wiring pattern 124 and may penetrate the lower dielectric pattern 122 to be coupled to a bottom surface of the lower wiring pattern 124 of an overlying lower wiring layer. For example, a lower portion of the lower wiring pattern 124 disposed below the lower dielectric pattern 122 may be a head part used as a horizontal connection line or pad, and the via of the lower wiring pattern 124 may be a tail part. The lower wiring pattern 124 may have an inverse T shape.

An external terminal 150 may be provided below the lower redistribution layer 120. The external terminal 150 may be disposed on a lower pad 124p provided on a bottom surface of the lower redistribution layer 120. The lower pad 124p may be a portion the lower wiring pattern 124 exposed on the bottom surface of the lower redistribution layer 120, or a discrete pad disposed on the lower dielectric pattern 122 of the lower redistribution layer 120 and connected to the lower wiring pattern 124. The external terminal 150 may include a solder ball or a solder bump. The lower pad 124p and the external terminal 150 may each be provided in plural.

The upper redistribution layer 130 may be provided on the top surface of the core section 110. The upper redistribution layer 130 may cover the top surface of the core section 110. The upper redistribution layer 130 may include one or more upper wiring layers that are sequentially stacked on the top surface of the core section 110. Each of the upper wiring layers may include an upper dielectric pattern 132 and an upper wiring pattern 134. The upper wiring pattern 134 of one upper wiring layer may be electrically connected to the upper wiring pattern 134 of an adjacent upper wiring layer. The following will describe the upper dielectric pattern 132 and the upper wiring pattern 134 of one upper wiring layer.

The upper dielectric pattern 132 may include a dielectric polymer or a photo-imageable dielectric (PID). The photo-imageable dielectric may include, for example, at least one selected from photosensitive polyimide, polybenzoxazole, phenolic polymers, and benzocyclobutene polymers.

The upper wiring pattern 134 may be provided on the upper dielectric pattern 132. The upper wiring pattern 134 may be provided on a top surface of the upper dielectric pattern 132. The upper wiring pattern 134 may protrude onto the top surface of the upper dielectric pattern 132. The upper wiring pattern 134 may horizontally extend on the top surface of the upper dielectric pattern 132. On the top surface of the upper dielectric pattern 132, the upper wiring pattern 134 may be covered with the upper dielectric pattern 132 of an overlying upper wiring layer. As discussed above, the upper wiring pattern 134 may be a pad or wiring part of the upper wiring layer. For example, the upper wiring pattern 134 may be a component for horizontal redistribution in the upper redistribution layer 130.

The upper wiring pattern 134 may not be electrically connected to the first thermal radiation structure 200. For example, the upper wiring pattern 134 may be spaced apart from the first thermal radiation structure 200 across the upper dielectric pattern 132 or the core section 110. For another example, when the first thermal radiation structure 200 is exposed on the top surface of the core section 110, the upper dielectric pattern 132 may separate the upper wiring pattern 134 from the first thermal radiation structure 200. Thus, the upper and lower wiring patterns 134 and 124 may be spaced apart from the first thermal radiation structure 200 in the core section 110. The upper wiring pattern 134 may include a conductive material. For example, the upper wiring pattern 134 may include copper (Cu).

The upper wiring pattern 134 may have a damascene structure. For example, the upper wiring pattern 134 may have a via that protrudes onto a bottom surface thereof. The via may be a component for a vertical connection between the upper wiring patterns 134 of neighboring upper wiring layers. For example, the via may extend from the bottom surface of the upper wiring pattern 134 and may penetrate the upper dielectric pattern 132 to be coupled to a top surface of the upper wiring pattern 134 of an underlying upper wiring layer. An upper portion of the upper wiring pattern 134 positioned on the upper dielectric pattern 132 may be a head part used as a horizontal wiring line or pad, and the via of the upper wiring pattern 134 may be a tail part. The via of the upper wiring pattern 134 may be electrically connected through the core through via 112 to the via of the lower wiring pattern 124. The upper wiring pattern 134 may have a T shape.

The head part of the upper wiring pattern 134 disposed on an uppermost of the upper wiring layers may correspond to upper pads for mounting a subsequently described interposer substrate 500 on the upper redistribution layer 130.

An interposer substrate 500 may be provided on the wiring substrate 100. The interposer substrate 500 may be mounted on a top surface of the upper redistribution layer 130. The interposer substrate 500 may include first substrate pads 510 exposed on a top surface thereof and second substrate pads 520 exposed on a bottom surface thereof. The first substrate pads 510 and the second substrate pads 520 may be electrically connected through one or more circuit lines in the interposer substrate 500. The first substrate pads 510 and the second substrate pads 520 may include a conductive material, such as metal. For example, the first substrate pads 510 and the second substrate pads 520 may include copper (Cu). The interposer substrate 500 may be formed of a dielectric material or silicon (Si). When the interposer substrate 500 includes silicon (Si), the interposer substrate 500 may be a silicon interposer substrate having a through electrode that vertically penetrates therethrough. The interposer substrate 500 may redistribute a first chip stack CS1 and a first semiconductor chip 300 which will be discussed below.

The interposer substrate 500 may be provided with substrate terminals disposed on the bottom surface thereof. The substrate terminals may be provided between the upper pads of the upper redistribution layer 130 and the second substrate pads 520 of the interposer substrate 500. The substrate terminals may electrically connect the interposer substrate 500 to the wiring substrate 100. The substrate terminals may include solder balls or solder bumps.

A first underfill layer 530 may be provided between the upper redistribution layer 130 and the interposer substrate 500. The first underfill layer 530 may surround the substrate terminals, while filling a space between the upper redistribution layer 130 and the interposer substrate 500.

On the central region CA, a first semiconductor chip 300 may be disposed on the top surface of the interposer substrate 500. When viewed in plan, the first semiconductor chip 300 may be disposed horizontally spaced apart from the first thermal radiation structure 200. For example, the first thermal radiation structure 200 may not be positioned below the first semiconductor chip 300. The first semiconductor chip 300 may be disposed in a face-down state on the interposer substrate 500. The first semiconductor chips 300 may have a bottom surface as an active surface.

The first semiconductor chip 300 may include a first semiconductor substrate 310. The first semiconductor substrate 310 may include a semiconductor material. For example, the first semiconductor substrate 310 may include silicon (Si). An integrated element or integrated circuits may be formed on a bottom surface of the first semiconductor substrate 310. The integrated element or the integrated circuits may include a logic circuit. For example, the first semiconductor chip 300 may be a logic chip.

A first wiring layer 320 may be provided on the bottom surface of the first semiconductor substrate 310. The first wiring layer 320 may have a first dielectric pattern 322 and a first wiring pattern 324 provided in the first dielectric pattern 322. On the bottom surface of the first semiconductor chip 300, the first dielectric pattern 322 may cover the integrated element or the integrated circuits. The first wiring pattern 324 may be coupled to the integrated element or the integrated circuits formed in the first semiconductor substrate 310.

The first semiconductor chip 300 may be mounted on the interposer substrate 500. For example, the first semiconductor chip 300 may be electrically connected through first connection terminals 330 to the interposer substrate 500. The first connection terminals 330 may be provided between the first substrate pads 510 and first pads provided on the bottom surface of the first semiconductor chip 300. The first pad may be a portion of the first wiring pattern 324 exposed from the first dielectric pattern 322 of the first wiring layer 320, or a discrete pad disposed on the first dielectric pattern 322 of the first wiring layer 320 to come into connection with the first wiring pattern 324. As the first semiconductor chip 300 is mounted through the first connection terminals 330 to the interposer substrate 500, the bottom surface of the first semiconductor chip 300 may be spaced apart from the interposer substrate 500.

A second underfill layer 340 may be provided between the top surface of the interposer substrate 500 and the bottom surface of the first semiconductor chip 300. The second underfill layer 340 may surround the first substrate pads 510, the first pads, and the first connection terminals 330, while filling a space between the interposer substrate 500 and the first semiconductor chip 300.

A first chip stack CS1 may be provided on the interposer substrate 500. The first chip stack CS1 may be provided on the peripheral region SA of the core section 110. The first chip stack CS1 may be positioned above the first thermal radiation structure 200. On the interposer substrate 500, the first chip stack CS1 may be disposed horizontally spaced apart from the first semiconductor chip 300. As shown in FIG. 3, the first chip stack CS1 may be disposed spaced apart in the first direction D1 or the second direction D2 from the first semiconductor chip 300. The first chip stack CS1 may include a base chip 600, second semiconductor chips 700 stacked on the base chip 600, and a first molding layer 740 that surrounds the second semiconductor chips 700. The following will describe in detail a configuration of the first chip stack CS1.

The base chip 600 may include a base substrate 610. The base substrate 610 may be a semiconductor substrate. For example, the base substrate 610 may be a wafer-level semiconductor substrate formed of a semiconductor material such as silicon (Si). The base chip 600 may have a bottom surface as an active surface. For example, an integrated element or integrated circuits may be formed on a bottom surface of the base substrate 610. The integrated element or the integrated circuits may include, for example, a memory circuit. For example, the base chip 600 may be a memory chip, such as a dynamic random access memory (DRAM), a static random access memory (SRAM), a magnetic random access memory (MRAM), or a Flash memory. Alternatively, the integrated element or the integrated circuits may include a logic circuit. In this case, the base chip 600 may be a logic chip.

The base chip 600 may include a base circuit layer 620 and a base through via 612. The base circuit layer 620 may be provided on the bottom surface of the base chip 600. The base circuit layer 620 may include the integrated element or the integrated circuits. The base through via 612 may penetrate the base chip 600 in a direction perpendicular to the top surface of the interposer substrate 500. The base through via 612 and the base circuit layer 620 may be electrically connected to each other.

The base chip 600 may further include a protection layer and second connection terminals 630. Although not shown, the protection layer may be disposed on the bottom surface of the base chip 600 to cover the base circuit layer 620. The protection layer may include silicon oxide (SiO) or silicon nitride (SiN). The second connection terminal 630 may be provided on the bottom surface of the base chip 600. The second connection terminal 630 may be electrically connected to the integrated element or the integrated circuit of the base circuit layer 620. The second connection terminal 630 may be provided in plural.

A second semiconductor chip 700 may be provided on the base chip 600. A width of the second semiconductor chip 700 may be less than that of the base chip 600. The base chip 600 and the second semiconductor chip 700 of the first chip stack CS1 may have their thicknesses less than that of the first semiconductor chip 300. The second semiconductor chip 700 may include a second semiconductor substrate 710, a second circuit layer 720, and a through via 712.

The second semiconductor substrate 710 may be a semiconductor substrate. For example, the second semiconductor substrate 710 may include silicon (Si). The second semiconductor chip 700 may have a bottom surface as an active surface. For example, an integrated element or integrated circuits may be formed on a bottom surface of the second semiconductor substrate 710. The integrated element or the integrated circuits may include, for example, a memory circuit. For example, the second semiconductor chip 700 may be a memory chip, such as a dynamic random access memory (DRAM), a static random access memory (SRAM), a magnetic random access memory (MRAM), or a Flash memory.

The second semiconductor chip 700 may include a second circuit layer 720 and a second through via 712. The second circuit layer 720 may be provided on the bottom surface of the second semiconductor chip 700. The second circuit layer 720 may include the integrated element or the integrated circuits. The through via 712 may penetrate the second semiconductor chip 700 in a direction perpendicular to the top surface of the upper redistribution layer 130. The through via 712 and the second circuit layer 720 may be electrically connected to each other. A plurality of connection bumps 730 may be provided on the bottom surface of the second semiconductor chip 700. The connection bumps 730 may reside between and electrically connect the base chip 600 and the second semiconductor chip 700. The connection bumps 730 may be electrically connected to the integrated element or the integrated circuits of the second circuit layer 720.

The second semiconductor chip 700 may be provided in plural. For example, a plurality of second semiconductor chips 700 may be stacked on the base chip 600. The number of stacked second semiconductor chips 700 may be about 8 to 32. The connection bumps 730 may be correspondingly provided between the second semiconductor chips 700. An uppermost second semiconductor chip 700 may not include the through via 712. In addition, the uppermost second semiconductor chip 700 may have a thickness greater than those of other second semiconductor chips 700 disposed thereunder.

Although not shown, adhesion layers may be provided between the second semiconductor chips 700. The adhesion layers may include a non-conductive film (NCF). The adhesion layers may surround the connection bumps 730 between the second semiconductor chips 700 and may prevent the occurrence of electrical shorts between the connection bumps 730.

The first molding layer 740 may be disposed on a top surface of the base chip 600. The first molding layer 740 may cover the top surface of the base chip 600. The first molding layer 740 may surround the second semiconductor chips 700. A top surface of the first molding layer 740 may be coplanar with that of the uppermost second semiconductor chip 700. The uppermost second semiconductor chip 700 may be exposed on the top surface of the first molding layer 740. The first molding layer 740 may include a dielectric polymer material. For example, the first molding layer 740 may include an epoxy molding compound (EMC).

The first chip stack CS1 may be mounted on the interposer substrate 500. For example, the first chip stack CS1 may be coupled through the second connection terminal 630 of the base chip 600 to the first substrate pads 510 disposed on the top surface of the interposer substrate 500. The second connection terminal 630 may be in contact with top surfaces of the first substrate pads 510 and a bottom surface of the base circuit layer 620 to come into electrical connection with the first chip stack CS1 and the interposer substrate 500.

A third underfill layer 640 may be provided between the interposer substrate 500 and the first chip stack CS1. The third underfill layer 640 may surround the first substrate pads 510 and the second connection terminals 630, while filling a space between the interposer substrate 500 and the base chip 600.

Referring to FIG. 3, widths in the first and second directions D1 and D2 of the first chip stack CS1 may be the same as or similar to widths in the first and second directions D1 and D2 of the first thermal radiation structure 200. When viewed in plan, at least a portion of the first thermal radiation structure 200 may vertically overlap the first chip stack CS1. The present disclosure, however, is not limited thereto. The widths in the first and second directions D1 and D2 of the first chip stack CS1 may be the same as or greater than the widths in the first and second directions D1 and D2 of the first thermal radiation structure 200. In this case, the first chip stack CS1 may vertically overlap the entirety of the first thermal radiation structure 200. For example, a planar area of the first thermal radiation structure 200 may be the same as or less than a planar area of the first chip stack CS1.

Heat generated from the first chip stack CS1 may be outwardly transferred through the first thermal radiation structure 200. For example, the heat generated from the first chip stack CS1 may be transferred to the first thermal radiation structure 200 through the interposer substrate 500 and the upper redistribution layer 130. The heat may be transferred through the first thermal radiation structure 200 to the lower redistribution layer 120. The heat transferred to the lower redistribution layer 120 may be outwardly discharged through the external terminals 150. For example, the first thermal radiation structure 200 may have a thermal conductivity greater than that of the core section 110, and the first chip stack CS1 may promptly discharge heat through an underlying first thermal radiation structure 200 toward a downside of the wiring substrate 100. Accordingly, it may be possible to provide a semiconductor package with improved thermal radiation properties.

Although not shown, a second molding layer may be disposed on the top surface of the interposer substrate 500. The second molding layer may surround the first semiconductor chip 300, the first underfill layer 530, the first chip stack CS1, and the second underfill layer 340. The second molding layer may have a top surface coplanar with that of the uppermost second semiconductor chip 700 in the first chip stack CS1 and that of the first semiconductor chip 300, and the first semiconductor chip 300 and the uppermost second semiconductor chip 700 may be exposed on the top surface of the second molding layer. The second molding layer may include a dielectric polymer material. For example, the second molding layer may include an epoxy molding compound (EMC).

In the implementations that follow, components the same as those discussed with reference to FIGS. 1 to 3 are allocated the same reference numerals thereto, and a repetitive explanation thereof will be omitted or abridged for convenience of description. The following description will focus on differences between the implementations of FIGS. 1 to 3 and other implementations discussed below.

FIG. 1 depicts that one first chip stack CS1 is provided, but the present disclosure is not limited thereto. A plurality of chip stacks may be provided.

FIG. 4 illustrates a plan view showing an example semiconductor package.

Referring to FIG. 4, identically or similarly to FIG. 1, the first semiconductor chip 300 and the first chip stack CS1 may be provided on the interposer substrate 500.

On the peripheral region SA, a semiconductor package may further include a second chip stack CS2 provided on the top surface of the interposer substrate 500. The second chip stack CS2 may be substantially the same as or similar to the first chip stack CS1 discussed with reference to FIG. 1. The first chip stack CS1 and the second chip stack CS2 may be disposed spaced apart from each other in the third direction D3 that intersects the first and second directions D1 and D2.

In addition, the semiconductor package may further include a second thermal radiation structure 210 positioned below the second chip stack CS2. The second thermal radiation structure 210 may be provided in the core section 110. The second thermal radiation structure 210 may be substantially the same as or similar to the first thermal radiation structure 200 discussed with reference to FIG. 1. For example, the second thermal radiation structure 210 may be provided in the core section 110 on the peripheral region SA and may be electrically insulated from the lower redistribution layer 120 and the upper redistribution layer 130. The second thermal radiation structure 210 may have a thermal conductivity greater than that of the core section 110. When viewed in plan, the first thermal radiation structure 200 may overlap the first chip stack CS1, and the second thermal radiation structure 210 may overlap the second chip stack CS2.

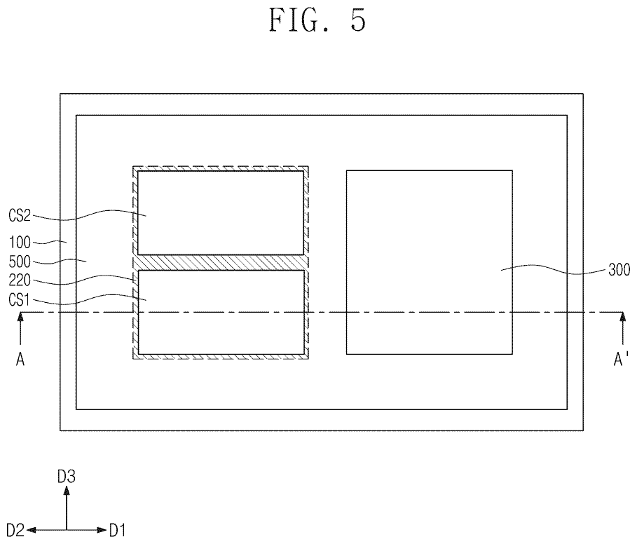

FIG. 5 illustrates a plan view showing an example semiconductor package.

Referring to FIG. 5, similarly to that discussed with reference to FIG. 4, a semiconductor package may include the first semiconductor chip 300, the first chip stack CS1, and the second chip stack CS2 that are disposed on the interposer substrate 500. The semiconductor package may include a third thermal radiation structure 220 the same as a structure which appears being obtained by connecting the first thermal radiation (see 200 of FIG. 4) and the second thermal radiation structure (see 210 of FIG. 4). The third thermal radiation structure 220 may have a shape which appears as if the first thermal radiation structure 200 and the second thermal radiation structure 210 are connected to each other with no interface therebetween. For example, the third thermal radiation structure 220 may extend along the third direction D3 from a location below the first chip stack CS1 toward a location below the second chip stack CS2. At least a portion the third thermal radiation structure 220 may vertically overlap the first chip stack CS1, and another portion of the third thermal radiation structure 220 may vertically overlap the second chip stack CS2.

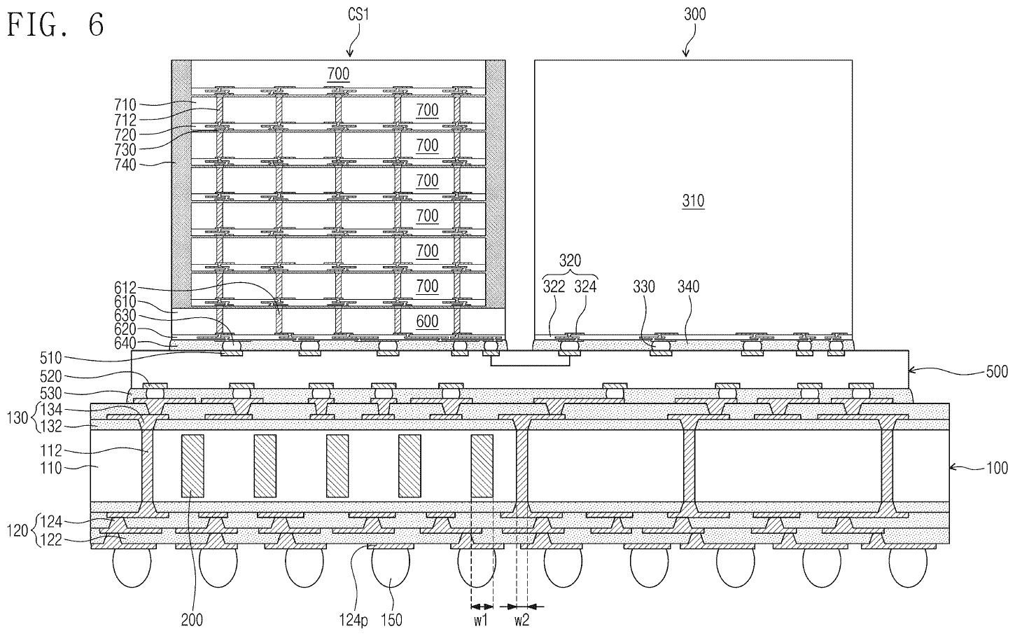

FIG. 6 illustrates a cross-sectional view showing an example semiconductor package.

Referring to FIG. 6, unlike the implementation of FIG. 1, the first thermal radiation structure 200 may be provided in plural, and each of the plurality of first thermal radiation structures 200 may include a metal post that is disposed vertically spaced apart from the first chip stack CS1. One end of each of the first thermal radiation structures 200 may not be connected to the upper wiring pattern 134 of the upper redistribution layer 130. The first thermal radiation structures 200 may be spaced apart from the upper redistribution layer 130. Another end of each of the first thermal radiation structures 200 may not be connected to the lower wiring patterns 124 of the lower redistribution layer 120. The first thermal radiation structures 200 may be spaced apart from the lower redistribution layer 120. For example, the first thermal radiation structures 200 may be spaced apart from the upper wiring pattern 134 and the lower wiring pattern 124 and electrically floated in the core section 110.

The first thermal radiation structures 200 may be formed of the same material as that of the core through vias 112. The material may include a conductive material, such as copper (Cu), aluminum (Al), silver (Ag), tin (Sn), gold (Au), nickel (Ni), lead (Pb), titanium (Ti), or any alloy thereof.

The first thermal radiation structures 200 may have a thermal conductivity greater than that of the core through vias 112. Even if substances are formed of a material having the same thermal conductivity, which is inherent properties of the substances, an increase in area of a cross-section perpendicular to a heat transfer direction in the substance may induce an increase in actual thermal conductivity. For example, the first thermal radiation structures 200 may be provided to have their large widths. The first thermal radiation structures 200 may have a first width W1 greater than a second width W2 of the core through vias 112. Therefore, the thermal conductivity of the first thermal radiation structures 200 may be greater than that of the core through vias 112. The first thermal radiation structures 200 may transfer heat whose amount is greater than that of heat transferred by the core through vias 112. In conclusion, there may be an increase in heat transfer efficiency along a vertical direction of the core section 110 in the wiring substrate 100.

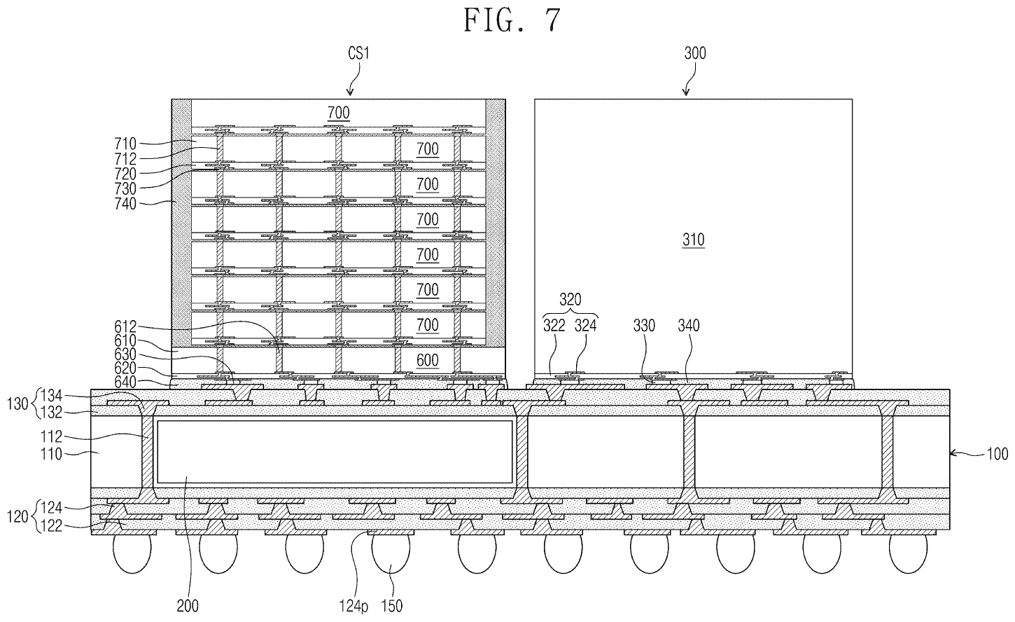

FIG. 7 illustrates a cross-sectional view showing an example semiconductor package.

Referring to FIG. 7, unlike the implementation of FIG. 1, the interposer substrate 500 may not be provided. The first semiconductor chip 300 may be provided on the wiring substrate 100. The first semiconductor chip 300 may be the same as that discussed with reference to FIG. 1.

The first semiconductor chip 300 may be disposed in a face-down state on the wiring substrate 100. The first semiconductor chip 300 may be mounted on the upper redistribution layer 130. For example, the first semiconductor chip 300 may be electrically connected through the first connection terminals 330 to the upper redistribution layer 130. The first connection terminals 330 may be provided between the upper pads of the upper redistribution layer 130 and first pads provided on the bottom surface of the first semiconductor chip 300. The first semiconductor chip 300 may be mounted through the first connection terminals 330 on the upper redistribution layer 130.

The second underfill layer 340 may be provided between the top surface of the upper redistribution layer 130 and the bottom surface of the first semiconductor chip 300. The second underfill layer 340 may surround the upper pads, the first pads, and the first connection terminals 330, while filling a space between the upper redistribution layer 130 and the first semiconductor chip 300.

The first chip stack CS1 may be provided on the upper redistribution layer 130. On the upper redistribution layer 130, the first chip stack CS1 may be disposed horizontally spaced apart from the first semiconductor chip 300. The first chip stack CS1 may be the same as that discussed with reference to FIG. 1. For example, the first chip stack CS1 may include the base chip 600, the second semiconductor chips 700 stacked on the base chip 600, and the first molding layer 740 that surrounds the second semiconductor chips 700.

The first chip stack CS1 may be mounted on the upper redistribution layer 130. For example, the first chip stack CS1 may be coupled through the second connection terminals 630 provided on the bottom surface of the base chip 600 to the upper pads disposed on the top surface of the upper redistribution layer 130. The second connection terminals 630 may be in contact top surfaces of the upper pads and the bottom surface of the base circuit layer 620 to come into connection with the first chip stack CS1 and the upper redistribution layer 130.

The third underfill layer 640 may be provided between the top surface of the upper redistribution layer 130 and a bottom surface of the first chip stack CS1. The third underfill layer 640 may surround the upper pads, an integrated element or integrated circuits, and the second connection terminals 630, while filling a space between the upper redistribution layer 130 and the first chip stack CS1.

As the first semiconductor chip 300 and the first chip stack CS1 are directly mounted on the wiring substrate 100, the interposer substrate 500 may not be disposed on the wiring substrate 100. A reduced distance may be provided between the first chip stack CS1 and the first thermal radiation structure 200 in the core section 110. For example, heat generated from the first chip stack CS1 may be promptly discharged to a downside of the wiring substrate 100, and a semiconductor package may improve in thermal radiation properties.

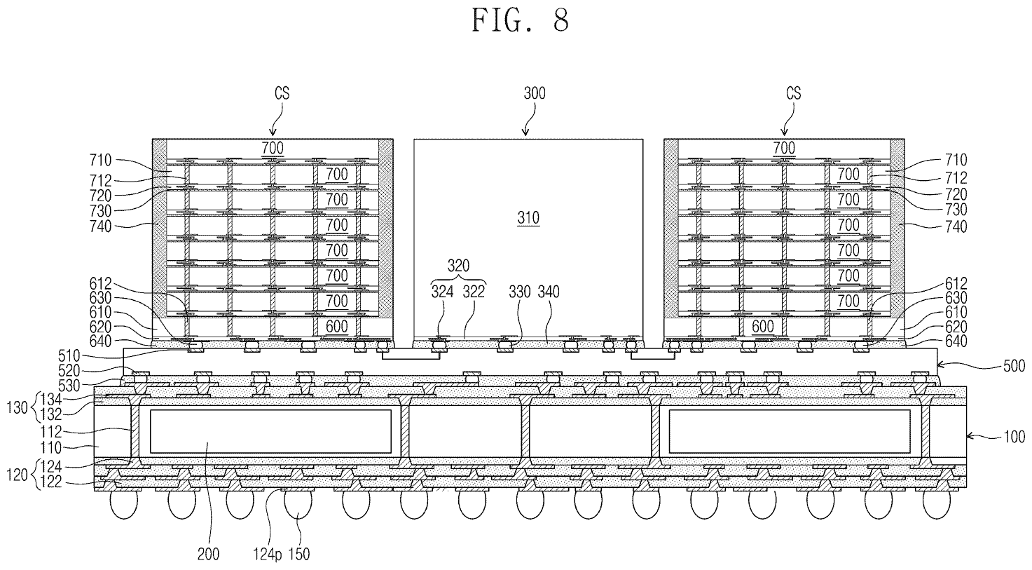

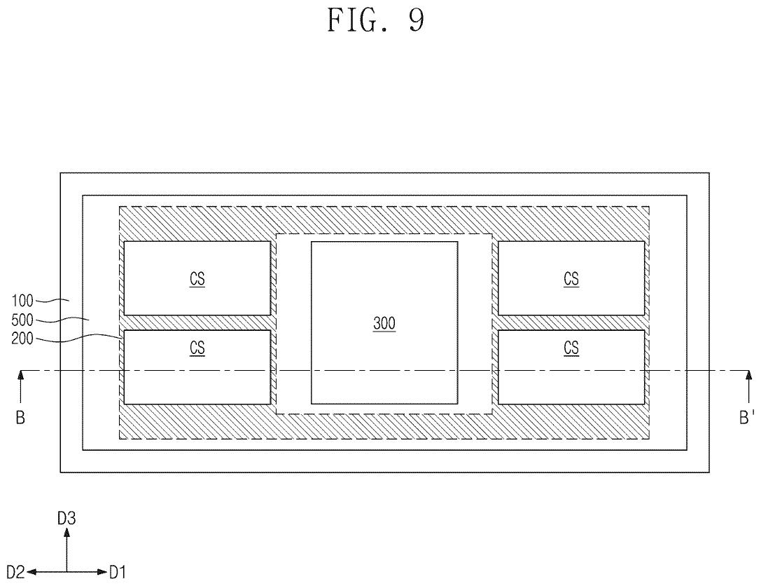

FIG. 8 illustrates a cross-sectional view showing an example semiconductor package. FIG. 9 illustrates a plan view showing an example semiconductor package. FIG. 8 shows a cross-sectional view taken along line B-B′ of FIG. 9.

Referring to FIG. 8, identically or similarly to that discussed with reference to FIG. 1, the first semiconductor chip 300 may be provided on the interposer substrate 500.

A plurality of chip stacks CS may be provided on the interposer substrate 500. The chip stacks CS may include a base chip 600, second semiconductor chips 700 stacked on the base chip 600, and a first molding layer 740 that surrounds the second semiconductor chips 700. The chip stacks CS may be substantially the same as or similar to the first chip stack CS1 of FIG. 1.

The chip stacks CS may be disposed spaced apart from each other on the interposer substrate 500. When viewed in plan, the first semiconductor chip 300 may be disposed between the chip stacks CS. For example, at least one chip stack CS may be disposed spaced apart in the first direction D1 from the first semiconductor chip 300, and at least one chip stack CS may be disposed spaced apart in the second direction D2, which is opposite to the first direction D1, from the first semiconductor chip 300. The chip stacks CS may surround the first semiconductor chip 300, and the first semiconductor chip 300 may be positioned between the chip stacks CS.

The first thermal radiation structure 200 may be provided within the core section 110. Referring to FIG. 9, the first thermal radiation structure 200 provided in single unitary form may vertically overlap all of the plurality of chip stacks CS. The first thermal radiation structure 200 may have a through hole that vertically penetrates therethrough. The through hole may be positioned below the first semiconductor chip 300. For example, the first thermal radiation structure 200 may overlap the chip stacks CS but may not overlap the first semiconductor chip 300. When viewed in plan, the first thermal radiation structure 200 may be disposed to surround the first semiconductor chip 300. For example, when viewed in plan, inner sidewalls of the first thermal radiation structure 200 may face lateral surfaces of the first semiconductor chip 300. The core section 110 may fill the through hole of the first thermal radiation structure 200. The first thermal radiation structure 200 may have an increased planar area, and thus a semiconductor package may improve in thermal radiation properties.

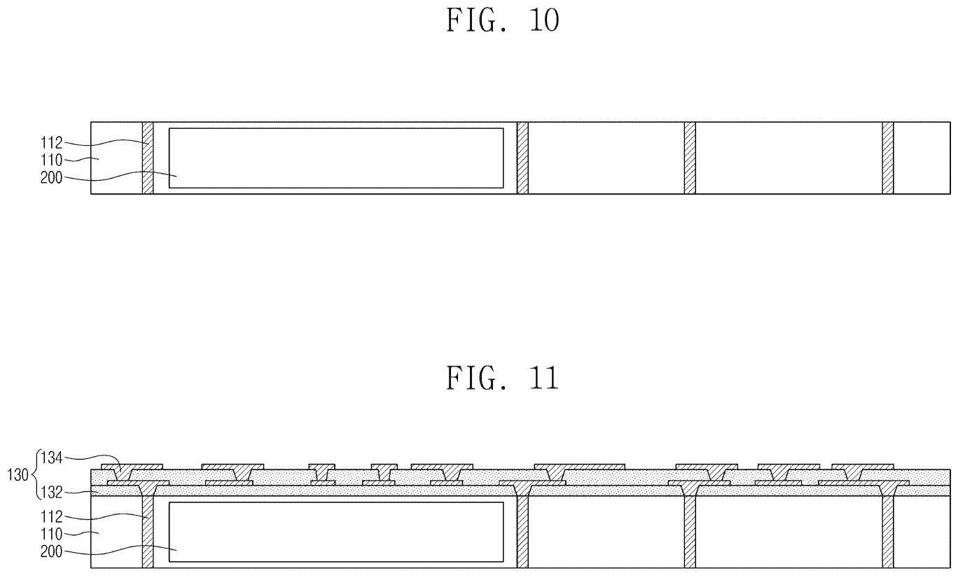

FIGS. 10 to 14 illustrate cross-sectional views showing an example method of fabricating an example semiconductor package.

Referring to FIG. 10, a first thermal radiation structure 200 may be provided. A prepreg formed of dielectric resin may be placed on top and bottom surfaces of the first thermal radiation structure 200 and may be thermally compressed to form a core section 110. A plurality of core through vias 112 may be formed in the core section 110. For example, the core through vias 112 may be formed by forming holes that penetrate the core section 110, and then filling the holes with a conductive material.

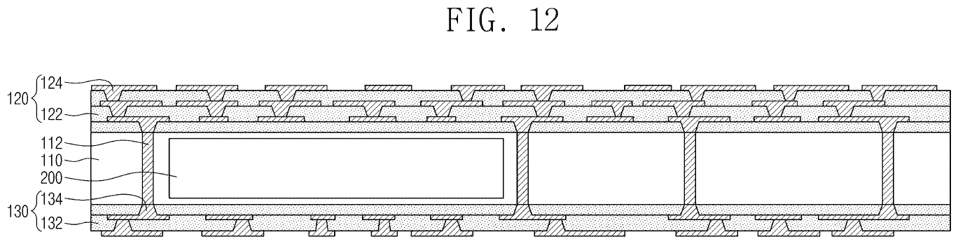

Referring to FIG. 11, an upper redistribution layer 130 may be formed on the core section 110. For example, a dielectric layer may be formed on a top surface of the core section 110, and then the dielectric layer may be patterned to form one upper dielectric pattern 132. A conductive layer may be formed on the upper dielectric pattern 132, and then the conductive layer may be patterned to form one upper wiring pattern 134. The process for forming the upper dielectric pattern 132 and the upper wiring pattern 134 may be repeatedly performed. A plurality of upper dielectric patterns 132 and a plurality of upper wiring patterns 134 may constitute the upper redistribution layer 130 discussed above with reference to FIG. 1.

Referring to FIG. 12, a resultant structure of FIG. 11 may be overturned. Thus, the upper redistribution layer 130 may be positioned below the core section 110.

A lower redistribution layer 120 may be formed on the core section 110. A dielectric layer may be formed on the top surface of the core section 110, and then the dielectric layer may be patterned to form one lower dielectric pattern 122. A conductive layer may be formed on the lower dielectric pattern 122, and then the conductive layer may be patterned to form one lower wiring pattern 124. The process for forming the lower dielectric pattern 122 and the lower wiring pattern 124 may be repeatedly performed. A plurality of lower dielectric patterns 122 and a plurality of lower wiring patterns 124 may constitute the lower redistribution layer 120 discussed above with reference to FIG. 1.

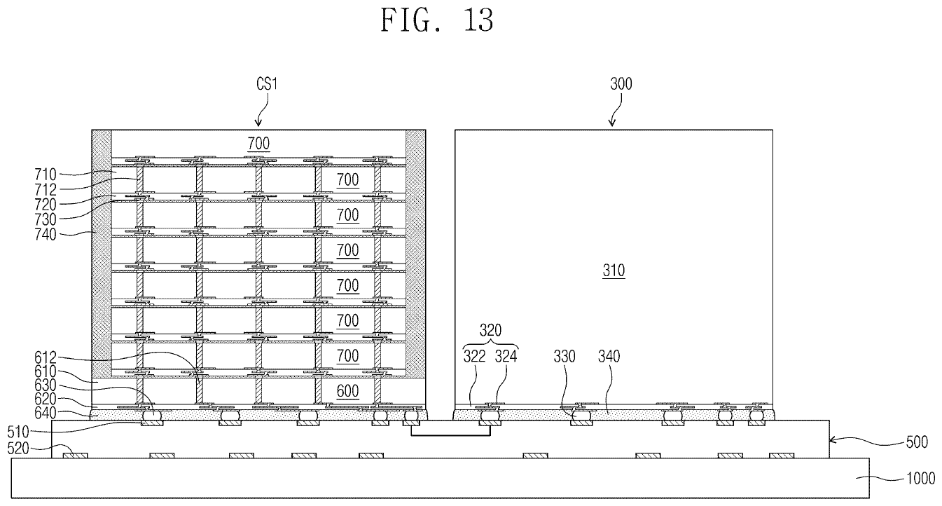

Referring to FIG. 13, a carrier substrate 1000 may be provided. An interposer substrate 500 may be formed on the carrier substrate 1000. The interposer substrate 500 may be the same as or similar to that discussed with reference to FIG. 1.

A first semiconductor chip 300 may be flip-chip mounted on the interposer substrate 500. The first semiconductor chip 300 may be the same as or similar to that discussed with reference to FIG. 1. For example, the first semiconductor chip 300 may include a first semiconductor substrate 310, a first wiring layer 320, and first connection terminals 330.

The first connection terminals 330 may be provided on a bottom surface of the first semiconductor chip 300. The first connection terminals 330 may include solder balls or solder bumps. The first semiconductor chip 300 may be aligned on the interposer substrate 500 to allow the first connection terminals 330 to reside on the first substrate pads 510 of the interposer substrate 500. The first semiconductor chip 300 may approach the interposer substrate 500, and the first connection terminals 330 may contact the first substrate pads 510. Afterwards, the first connection terminals 330 may undergo a reflow process to allow the first connection terminals 330 to connect the first pads to the first substrate pads 510. The first semiconductor chip 300 may be provided on its bottom surface with a second underfill layer 340 that surrounds the first connection terminals 330.

A first chip stack CS1 may be flip-chip mounted on the interposer substrate 500. The first chip stack CS1 may be the same as or similar to that discussed with reference to FIG. 1. For example, the first chip stack CS1 may include a base chip 600, second semiconductor chips 700 stacked on the base chip 600, and a first molding layer 740 that surrounds the second semiconductor chips 700.

A plurality of second connection terminals 630 may be provided on a bottom surface of the first chip stack CS1. The second connection terminals 630 may include solder balls or solder bumps. The first chip stack CS1 may be aligned on the interposer substrate 500 to allow the second connection terminals 630 to reside on the first substrate pads 510. The first chip stack CS1 may approach the interposer substrate 500, and the second connection terminals 630 may contact the first substrate pads 510. Afterwards, the second connection terminals 630 may undergo a reflow process to allow the second connection terminals 630 to connect the base circuit layer 620 to the first substrate pads 510. The first chip stack CS1 may be provided on its bottom surface with a third underfill layer 640 that surrounds the second connection terminals 630. For example, the third underfill layer 640 may be a non-conductive adhesive or a non-conductive film. When the third underfill layer 640 is a non-conductive adhesive, the third underfill layer 640 may be formed by dispensing a liquid non-conductive adhesive to coat the first chip stack CS1. When the third underfill layer 640 is a non-conductive film, the third underfill layer 640 may be formed by attaching a non-conductive film to the first chip stack CS1.

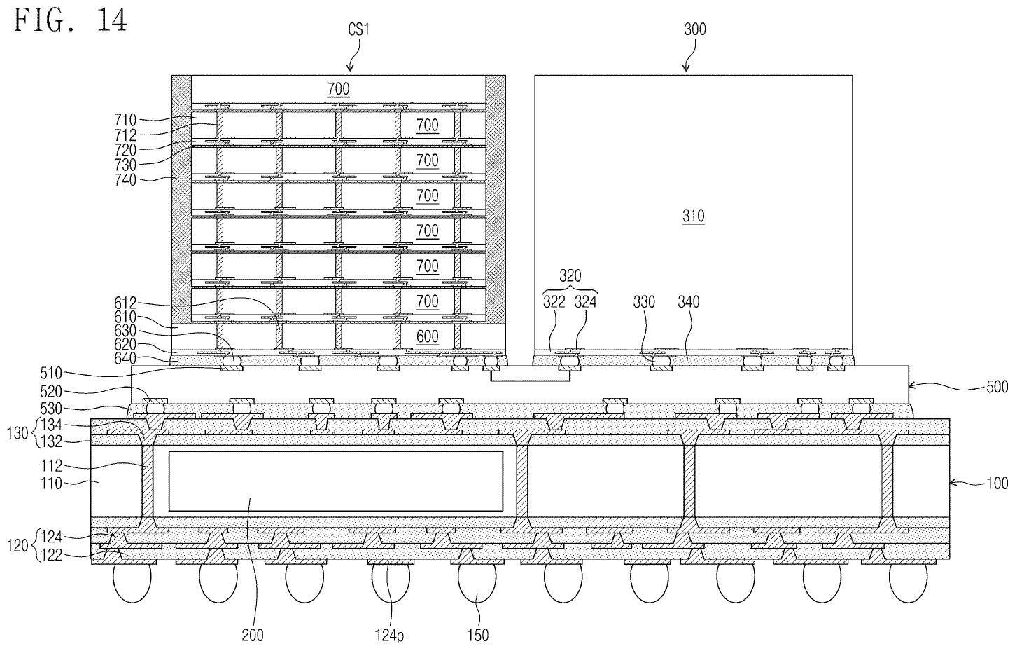

Referring to FIG. 14, a resultant structure of FIG. 12 may be overturned. Thus, the upper redistribution layer 130 may be positioned above the core section 110. The carrier substrate 1000 may be removed, and then a resultant structure of FIG. 13 may be mounted on the upper redistribution layer 130 of a wiring substrate 100. For example, the carrier substrate 1000 may be removed to expose a bottom surface of the interposer substrate 500. The interposer substrate 500 may be mounted on the upper redistribution layer 130. A plurality of substrate terminals may be provided on the bottom surface of the interposer substrate 500. The substrate terminals may be provided on the second substrate pads 520 of the interposer substrate 500. The substrate terminals may be coupled to upper pads of the upper redistribution layer 130. A first underfill layer 530 may be formed between the interposer substrate 500 and the upper redistribution layer 130. For example, after the interposer substrate 500 is provided on its bottom surface with the first underfill layer 530 that surrounds the substrate terminals, the interposer substrate 500 may be mounted on the wiring substrate 100.

A plurality of external terminals 150 may be disposed on a bottom surface of the lower redistribution layer 120. The external terminals 150 may be provided on bottom surfaces of lower pads 124p exposed on the bottom surface of the lower redistribution layer 120. For example, the external terminals 150, such as solder balls or solder bumps, may be attached to bottom surfaces of the lower pads 124p. As such, a semiconductor package of FIG. 1 may be fabricated.

In a semiconductor package according to some implementations of the present disclosure, a thermal radiation metal may be inserted into a core section of a substrate, and thus the semiconductor package may improve in thermal radiation properties.

In addition, as the thermal radiation metal is inserted into the core section of the substrate, it may be possible to prevent warpage of the substrate and to provide the semiconductor package with improved structural stability.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the present disclosure have been described in connection with the accompanying drawings, it will be understood by one of ordinary skill in the art that variations in form and detail may be made therein without departing from the spirit and essential features of the present disclosure. The above disclosed implementations should thus be considered illustrative and not restrictive.

What is claimed is:

1. A semiconductor package comprising:
a wiring substrate;
an external connection terminal on a bottom surface of the wiring substrate;
an interposer substrate on a top surface of the wiring substrate;
a first semiconductor chip on the interposer substrate; and
a first chip stack on the interposer substrate and horizontally spaced apart from the first semiconductor chip,
wherein the wiring substrate includes:
a core section;
an upper redistribution layer that covers a top surface of the core section; and
a lower redistribution layer that covers a bottom surface of the core section,
wherein the core section includes:
a plurality of core through-vias that vertically penetrate the core section; and
a first thermal radiation structure below the first chip stack and in the core section,
wherein the first thermal radiation structure is electrically insulated from the upper and lower redistribution layers, and
wherein a thermal conductivity of the first thermal radiation structure is greater than a thermal conductivity of the core section.

2. The semiconductor package of claim 1, wherein, when viewed in plan, the first thermal radiation structure is horizontally spaced apart from the first semiconductor chip.

3. The semiconductor package of claim 1, wherein the first thermal radiation structure vertically penetrates the core section and is exposed on the top and bottom surfaces of the core section.

4. The semiconductor package of claim 1, wherein
the first thermal radiation structure is spaced apart from the top and bottom surfaces of the core section, and
the core section separates the upper and lower redistribution layers from the first thermal radiation structure.

5. The semiconductor package of claim 1, further comprising:
a second chip stack on the interposer substrate and spaced apart in a first direction from the first chip stack; and
a second thermal radiation structure below the second chip stack and in the core section,
wherein the first thermal radiation structure vertically overlaps the first chip stack, and
wherein the second thermal radiation structure vertically overlaps the second chip stack.

6. The semiconductor package of claim 5, wherein
the first semiconductor chip is spaced apart in a second direction from the first chip stack, the second direction intersecting the first direction,
the first thermal radiation structure and the second thermal radiation structure are connected into a single thermal radiation structure, and
the single thermal radiation structure vertically overlaps all of the first and second chip stacks.

7. The semiconductor package of claim 5, wherein
the first semiconductor chip is between the first chip stack and the second chip stack,
the first thermal radiation structure and the second thermal radiation structure are connected into one thermal radiation structure, and
when viewed in plan, the one thermal radiation structure surrounds the first semiconductor chip.

8. The semiconductor package of claim 1, wherein the first thermal radiation structure includes at least one metal post in the core section.

9. The semiconductor package of claim 8, wherein
the first thermal radiation structure incudes a plurality of metal posts in the core section, and
a width of each metal post of the plurality of metal posts is greater than a width of each core through-via of the core through-vias.

10. A semiconductor package comprising:
a first redistribution layer;
a core section on the first redistribution layer, the core section having a central region and a peripheral region that surrounds the central region;
a thermal radiation metal in the core section on the peripheral region;
a second redistribution layer on the core section;
a first chip stack on the second redistribution layer on the peripheral region, the first chip stack including a plurality of memory chips vertically stacked; and
a logic chip on the second redistribution layer on the central region and horizontally spaced apart from the first chip stack,
wherein the thermal radiation metal is spaced apart from top and bottom surfaces of the core section.

11. The semiconductor package of claim 10, further comprising a second chip stack on the second redistribution layer on the peripheral region,
wherein the first chip stack and the second chip stack are spaced apart from each other in a first direction, and
wherein the logic chip is spaced apart in a second direction from the first chip stack, the second direction intersecting the first direction.

12. The semiconductor package of claim 11, wherein, when viewed in plan, the thermal radiation metal extends from a location below the first chip stack to a location below the second chip stack.

13. The semiconductor package of claim 10, wherein the core section is formed of a dielectric material.

14. The semiconductor package of claim 10, wherein the core section includes a through-via that vertically penetrates the core section and that electrically connects the first redistribution layer and the second redistribution layer to each other,
wherein the thermal radiation metal includes at least one metal post in the peripheral region.

15. The semiconductor package of claim 14, wherein
a first width of at least one metal post is greater than a second width of the through-via, and
the at least one metal post is electrically insulated from the first and second redistribution layers.

16. A semiconductor package, comprising:
a core section;
a thermal radiation structure in the core section;
a first redistribution layer and a second redistribution layer respectively on a top surface and a bottom surface of the core section, each of the first and second redistribution layers including a dielectric pattern and a wiring pattern in the dielectric pattern;
an interposer substrate on the first redistribution layer;
a first semiconductor chip on the interposer substrate; and
a plurality of chip stacks on the interposer substrate and horizontally spaced apart from the first semiconductor chip, each of the plurality of chip stacks including a plurality of second semiconductor chips that are vertically stacked,
wherein the thermal radiation structure vertically overlaps the plurality of chip stacks.

17. The semiconductor package of claim 16, wherein, when viewed in plan, the thermal radiation structure is horizontally spaced apart from the first semiconductor chip.

18. The semiconductor package of claim 17, wherein
the thermal radiation structure forms a through hole that penetrates the thermal radiation structure,
the core section fills the through-hole, and
the through-hole is below the first semiconductor chip.

19. The semiconductor package of claim 16, wherein the core section extends between the thermal radiation structure and the first redistribution layer and between the thermal radiation structure and the second redistribution layer.

20. The semiconductor package of claim 16, further comprising at least one through-via that penetrates the core section and connects the first redistribution layer and the second redistribution layer to each other.
